(19) United States
(12) Patent Application Publication
(10) Pub. No.: US 2026/0060092 A1
(43) Pub. Date: Feb. 26, 2026

(54) Vertical interconnect micro-component and method for producing a vertical interconnect micro-component

(71) Applicants: SCHOTT AG, Mainz (DE); SCHOTT GLASS TECHNOLOGIES (SUZHOU) CO. LTD., Suzhou, Jiangsu (CN)

(72) Inventors: Xiaofei BAI, Suzhou, Jiangsu (CN); Tobias GOTSCHKE, Gau-Bischofsheim (DE); Martin LETZ, Mainz (DE); Bernd HOPPE, Ingelheim (DE)

(21) Appl. No.: 19/102,664

(22) PCT Filed: Aug. 19, 2022
(86) PCT No.: PCT/CN2022/113583

§ 371 Date: Feb. 10, 2025

(51) Int. Cl. H01L 23/66; H01L 21/48; H01L 23/15; H01L 23/498

(52) U.S. Cl. CPC H01L 23/66; H01L 21/486; H01L 23/49827; H01L 23/49838; H01L 23/15; H01L 2223/6622

(57) ABSTRACT

A vertical interconnect micro-component adapted for radio frequency signal transmission, preferably for the use in three-dimensional integrated circuits, including: a glass substrate with a first side and a second side opposite to the first side, at least one inner through connector formed in the glass substrate, wherein the inner through connector includes an inner cavity in the glass substrate extending from the first side to the second side of the glass substrate, the inner cavity being fully or partially filled with solid conductor material, and an outer through connector structure formed in the glass substrate and surrounding the at least one inner through connector, the outer through connector structure including one or more outer cavities in the glass substrate extending from the first side to the second side of the glass substrate, the one or more outer cavities each being fully or partially filled with solid conductor material.

The invention relates to vertical interconnect micro-components adapted for radio frequency signal transmission which may be used in three-dimensional integrated circuits.

### BACKGROUND

In the field of integrated circuits, three-dimensionally structured systems and microsystems have become an increasingly relevant technology for increasing integration density. Vertical interconnection of such layered systems can be achieved by interconnect components comprising hole structures in which material is deposited in multi-stage processes to form vertical transmission lines.

For example, CN111180423A shows a mixed-base through hole micro-coaxial structure for vertical interconnection of a radio frequency micro-system and a manufacturing method thereof. A silicon wafer comprises a TSV hole structure, and a seed layer is arranged on the inner wall of the TSV hole structure and completely covers the inner wall of the TSV hole structure; an insulating layer is arranged on the seed layer and completely covers the seed layer; the TSV hole structure is filled with a glass medium, a through hole is formed in the glass medium, and a signal line is arranged in the through hole.

### SUMMARY OF THE INVENTION

However, such processes and resulting components are rather complex, may be prone to flaws and are expensive. Moreover, hole structures may still occupy larger areas than desired for high-density integration. Furthermore, rather high dielectric losses may occur.

An object of the present invention is to provide a vertical interconnect micro-component which is structurally simpler, less prone to errors and cheaper to manufacture.

The component should further comprise structures reduced in size in order to achieve higher integration density.

Furthermore, dielectric losses should be minimized. A further alternate or additional object of the invention is also to provide a method for producing such vertical interconnect micro-component.

The present invention provides a vertical interconnect micro-component adapted for radio frequency signal transmission, preferably for the use in three-dimensional integrated circuits comprising a substrate, at least one inner through connector formed in the substrate, and an outer through connector structure formed in the substrate.

The substrate comprises a first side and a second side opposite to the first side and comprises or consists of glass, i.e. the substrate is a glass substrate.

The at least one inner through connector formed in the glass substrate comprises an inner cavity in the glass substrate extending from the first side to the second side of the glass substrate, wherein the inner cavity is fully or partially filled with solid conductor material.

The outer through connector structure formed in the glass substrate comprises one or more outer cavities in the glass substrate extending from the first side to the second side of the glass substrate, wherein the one or more outer cavities are each fully or partially filled with solid conductor material.

In other words, the disclosed vertical interconnect micro-component is based on a glass substrate and is configured, for radio frequency transmission, for example by means of appropriate materials and dimensions.

The outer through connector structure surrounds the at least one inner through connector.

In an embodiment of the invention, the outer through connector structure comprises a plurality of spaced-apart annularly and/or symmetrically arranged outer cavities in the glass substrate extending from the first side to the second side of the glass substrate, wherein the spaced-apart outer cavities are each fully or partially filled with solid conductor material.

In a limiting case, the outer through connector structure may comprise two outer cavities symmetrically surrounding the inner through connector.

In another embodiment of the invention, the outer through connector structure comprises a continuous annular outer cavity in the glass substrate extending from the first side to the second side of the glass substrate, wherein the continuous outer cavity is fully or partially filled with solid conductor material.

In a preferred embodiment, the inner through connector is arranged coaxially and/or symmetrically in the center of the outer through connector structure.

Preferably the vertical interconnect micro-component comprises only one inner through connector. However, it is also possible that the vertical interconnect micro-component comprises a plurality of inner through connectors, which, preferably, are arranged in central symmetry with respect to the outer through connector structure. In other words, the vertical interconnect micro-component may include multiple inner through connectors, preferably surrounded by a circle of outer cavities.

In an embodiment, the vertical interconnect micro-component is adapted for the transmission of at least one frequency in the range of 1 MHz to 300 GHz, preferably in the range of 1 GHz to 200GHz, more preferably in the range of 5GHz to 100GHz.

The vertical interconnect micro-component may be adapted such as to define an upper cutoff frequency, i.e. a highest transmissible frequency, wherein the upper cutoff frequency is below 300 GHz, preferably below 200 GHz, more preferably below 100 GHZ.

In an embodiment, the vertical interconnect micro-component defines a characteristic impedance in the range of 30 Ohm to 100 Ohm, preferably in the range of 50 Ohm to 100 Ohm, more preferably in the range of 50 Ohm to 75 Ohm.

The inner through connector and outer through connector structure may, for example, have dimensions as follows.

The at least one inner through connector defines an outer diameter 2a, wherein the outer diameter 2a may be in the range of 1 μm to λ, preferably in the range of 1 μm to 1000 μm, more preferably in the range of 1 μm to 500 μm.

The outer through connector structure defines an inner diameter 2b, wherein the inner diameter 2b may be in the range of 1 μm to λ, preferably in the range of 1 μm to 1100 μm, more preferably in the range of 1 μm to 550 μm.

The aforementioned wavelength λ preferably is the upper wavelength of a microwave band selected from the group consisting of: L band, S band, C band, X band, Kᵤ band, K band, Kₐ band, Q band, U band, V band, W band, F band, D band, or a band above the D band, a band with an upper frequency of 300 GHz.

The outer cavities of the outer through connector structure may preferably have the same size and/or shape as the inner cavity of the inner through connector.

With regard to the substrate it may be envisaged that the relative permittivity (εᵣ) of the glass substrate at 5 GHz is lower than 10, preferably in the range of 1.0 to 5.0, more preferably in the range of 3.6 to 4.6, even more preferably in the range of 3.8 to 4.3, even more preferably in the range of 3.9 to 4.2.

In an embodiment, the thickness of the glass substrate is in the range of 0.03 mm to 3 mm, preferably in the range of 0.05 mm to 1 mm, more preferably in the range of 0.1 mm to 0.3 mm.

The solid conductor material which is embedded in the inner cavity and/or in the one or more outer cavities may in particular be a metal, preferably a metal selected from the group consisting of copper, aluminum, gold, palladium, carbon.

In particular as a result of the manufacturing process of the inner and/or outer cavities in the glass substrate, which is outlined further below, the inner and/or outer cavities may have specific characteristics.

The inner cavity and/or the one or more outer cavities may, for example, be characterized by a wall having a plurality of rounded, substantially hemispherical depressions that, preferably, adjoin one another.

Preferably, said plurality of rounded, substantially hemispherical depressions have abutting concave roundings, which form ridges.

Further preferably, said ridges form polygonal delimiting lines as viewed in a plan-view of said plurality of rounded, substantially hemispherical depressions.

With this invention it is also disclosed a method for producing a vertical interconnect micro-component, in particular according as outlined above.

The method comprises providing a glass substrate with a first side and a second side opposite to the first side.

The method further comprises producing at least one inner cavity and at least one outer cavity by directing a laser beam onto one of the sides of the glass substrate to form filament-shaped flaws in the volume of the glass substrate and, preferably, exposing the filament-shaped flaws to an etching medium to form the at least one inner cavity and at least one outer cavity and/or to produce smooth perpendicular walls. The Etching medium may for example be an alkali or acidic based etching solution.

The method further comprises embedding a solid conductor material in the at least one inner cavity and at least one outer cavity to form at least one inner through connector and an outer through connector structure in the glass substrate.

In an embodiment of the method, the embedding of solid conductor material comprises depositing an adhesion layer on the wall of the respective cavity.

Preferably, the adhesion layer comprises titanium, chromium, and/or nickel.

Preferably, the adhesion layer is deposited by physical vapor deposition, by dip coating, or by chemical vapor deposition or atomic layer deposition.

In an embodiment of the method, the embedding of a solid conductor material comprises depositing a seed layer on the wall of the respective cavity or on the adhesion layer.

Preferably, the seed layer comprises copper, and, further preferably, the seed layer is deposited by physical vapor deposition, by electroless plating or by chemical vapor deposition or atomic layer deposition.

In an embodiment of the method, the embedding of a solid conductor material comprises fully or partially filling the respective cavity, preferably after depositing an adhesion layer and/or a seed layer, with a conductor material.

Preferably, the conductor material, which is fully or partially filled in the cavity, comprises copper, and, further, preferably, the filling is applied by electroplating.

In a further embodiment of the method, after embedding a solid conductor material in the at least one inner cavity and at least one outer cavity, excess material may be removed from at least one of the sides of the glass substrate.

With the invention it is further disclosed an integrated circuit comprising a vertical interconnect micro-component as described above, wherein the integrated circuit may, for example, be a microelectromechanical system (MEMS), an image sensor (CIS), a memory (FLASH, DRAM), a processing unit (CPU), a graphics processing unit (GPU), a power supply, a power amplifier, a field programmable gate array (FPGA).

Furthermore, a vertical interconnect micro-component according to the present invention may comprise multiple structures of inner and outer through connectors on a single glass substrate.

### BRIEF DESCRIPTION OF THE DRAWINGS

In what follows, the invention is described in more detail with reference to the figures:

FIG. 1 is a top view on a first embodiment of a vertical interconnect micro-component,

FIG. 2 is a top view on a second embodiment of a vertical interconnect micro-component,

FIG. 3 is a side view on several steps of a method for producing a vertical interconnect micro-component,

FIG. 4 is a top view on a third embodiment of a vertical interconnect micro-component,

FIG. 5 is a diagram showing the cutoff frequency of a vertical interconnect micro-component for varying parameters of an exemplary vertical interconnect micro-component.

FIG. 6 is a top view on a fourth embodiment of a vertical interconnect micro-component.

### DETAILED DESCRIPTION

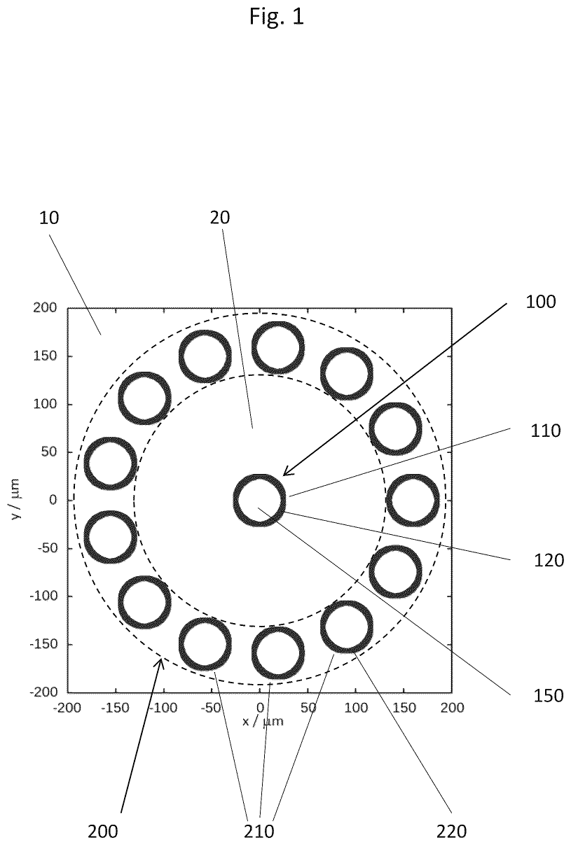

FIG. 1 shows a vertical interconnect micro-component with a glass substrate 10 in which a central inner through connector 100 and an annular outer through connector structure 200 is formed.

The inner through connector 100 comprises a single inner cavity 110 in the glass substrate 10 and solid conductor material 120 embedded therein. In this embodiment, the solid conductor material 120 is formed as a layer on the internal wall of the inner cavity 110. Thus, in this embodiment, the inner cavity 110 is partially filled with solid conductor material 120 and a free space 150 remains in the center of the inner cavity 110. However, the free space 150 may be filled with another material, for example an epoxy material.

The outer through connector structure 200 comprises a plurality of individual spaced-apart outer cavities 210, which are arranged symmetrically around the inner through connector 100. In this embodiment, an uneven number of outer cavities 210 is arranged in a circumferential configuration around the inner connector 100. In this case, the outer cavities 210 are formed in the same way as the inner cavity 110. In particular, the outer cavities 210 have the same shape and size as the inner cavity 110 and, again, solid conductor material 220 is embedded in each of the outer cavities 210 as a layer on their internal walls.

Together, the inner through connector 100 and the outer through connector structure 200 form a coaxial-like structure with an insulation area 20 in between, wherein the insulation area 20 is formed by the glass substrate 10 itself. Thus, the insulation area 20 provides high resistance, improving the signal quality of the vertical interconnect micro-component, without requiring additional application of insulation material.

Preferably, the position tolerance of inner and/or outer cavities in the substrate is ±3 μm.

Generally, the individual cavity diameter may for example be in the range of 20 to 70 μm, more preferably in the range of 40 to 50 μm. The total dimension of the outer through connector structure 200 may for example be in the range of 300 to 400 μm in diameter. The outer through connector structure 200 may for example comprise a number of cavities in the range of for example 7 to 10. The cavities of the outer through connector structure 200 may again be in the range of 20 to 70 μm in diameter, more preferably in the range of 40 to 50 μm. The inner and/or outer cavities are preferably round. The form of inner and/or outer cavity volume shape is preferably straight.

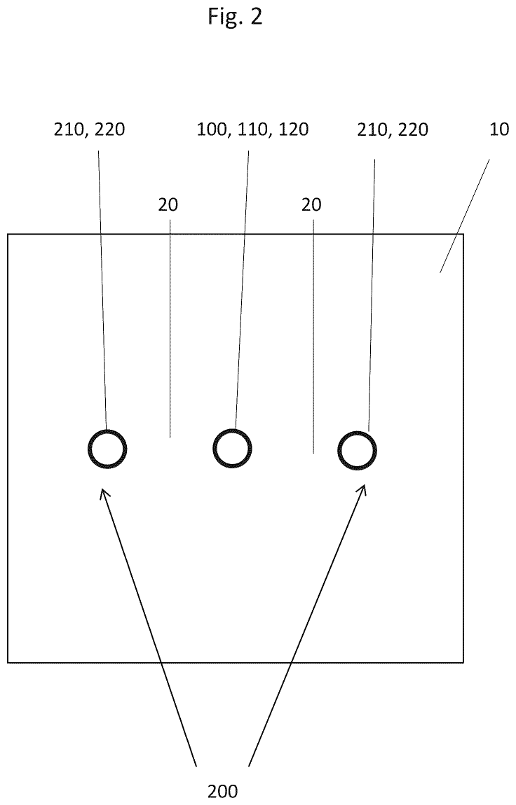

FIG. 2 shows a limiting case embodiment of a vertical interconnect micro-component comprising an outer through connector structure 200 with two outer cavities 210 which are diametrically opposed to the central inner through connector 100.

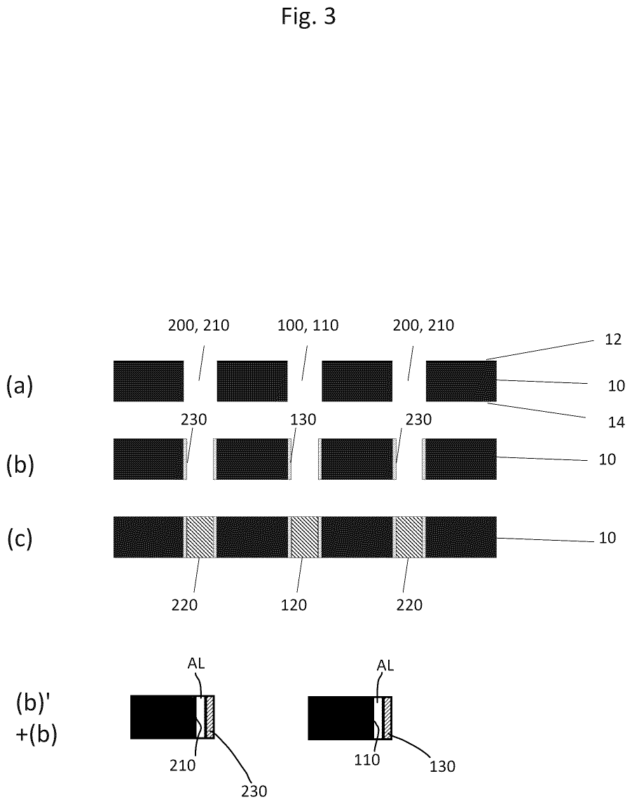

FIG. 3 shows side views on several steps of a method for producing a vertical interconnect micro-component.

In step (a) an inner cavity 110 and one or more outer cavities 210 are introduced into the glass substrate 10.

The cavities 110, 210 may be produced by directing a laser beam onto one of the sides 12, 14 of the glass substrate 10 to form filament-shaped flaws along the thickness of the glass substrate 10. Subsequently, the filament-shaped flaws may be exposed to an etching medium to form the cavities 110, 210 in the glass substrate 10.

The inner cavity 110 and one or more outer cavities 210 each extend completely through the thickness of the glass substrate 10, that is from the first side 12 to the second side 14 of the glass substrate 10.

In step (b), the inner cavity 110 and the one or more outer cavities 210 are each coated on their internal walls with a metallic seed layer 130, 230, which, for example comprising copper. Such seed layer may, for example, be deposited by physical or chemical vapor deposition, atomic layer deposition, or electroless plating.

Prior to coating the internal walls of the cavities 110, 210 with the seed layer 130, 230, an adhesion layer shown solely schematically as AL in (b)′+(b) may be applied or created on the internal walls of the cavities 110, 210. Such adhesion layer may comprise titanium, chromium, and/or nickel, for example. The adhesion layer may, for example, be deposited by physical or chemical vapor deposition, atomic layer deposition or dip coating. However, it may also be envisaged to modify a superficial layer of the internal wall by physically or chemically activating the surface of the wall to increase surface adhesion.

In step (c), solid conductor material 120, 220 is embedded in the cavities 110, 120 so that the cavities are partially or fully filled with the solid conductor material 120, 220. In the illustrated example, the cavities 110, 210 are fully filled. The embedding of the solid conductor material 120, 220 preferably is performed by electroplating.

After fully or partially filling the cavities 110, 210 with the conductor material, excess material may be removed from the sides 12, 14 of the glass substrate 10. This can be achieved by etching and/or mechanical polishing. After filling the cavities and/or removing excess material, a redistribution layer may be prepared by photolithography.

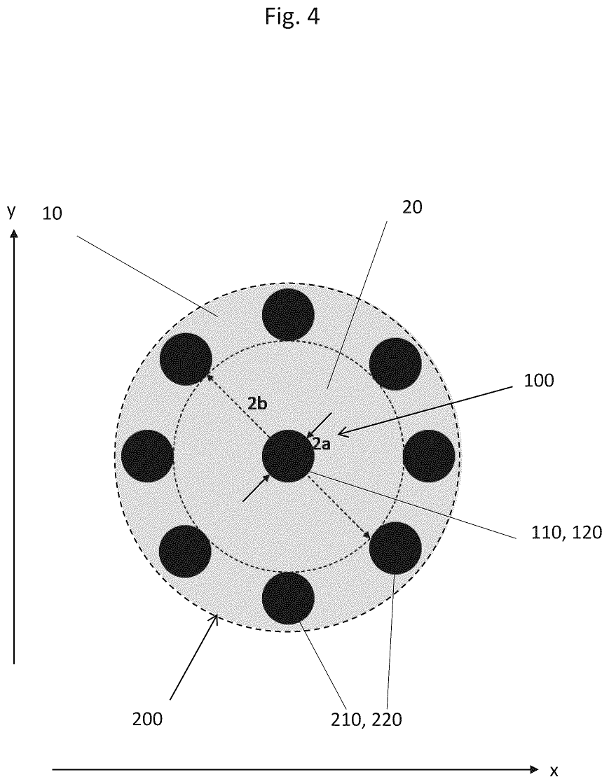

FIG. 4 shows an example of a resulting embodiment of a vertical interconnect micro-component comprising inner and outer cavities 110, 210, which are fully filled with solid conductor material 120, 220 to form the inner through connector 100 and the outer through connector structure 200.

Generally, without limitation to this embodiment, the inner through connector 100 may define an outer diameter 2a and the outer through connector structure 200 may define an inner diameter 2b.

The characteristic impedance Z₀ may be approximated by the formula

$${Z}_{0} = \frac{60}{\sqrt{{ε}_{r}}} ln \frac{b}{a} ,$$

where εᵣ is the relative permittivity of the glass substrate 10 and, thus, the insulation area 20. By means of a glass substrate having a small εᵣ, the area in the x-y direction required for the structures for the vertical interconnect micro-component can be reduced, in particular when compared to Si substrates. If Si is used for the structures, due to larger dielectric constant, for high frequency application, it may cause the vertical interconnection structure to occupy a larger area of the substrate in the x-y direction, which may be a disadvantage for achieving high-density packaging of components on a substrate, for example in areas of high power computing.

A vertical interconnect micro-component comprising a glass substrate may for example have a target impedance value for high frequency applications in the range of 50 to 70Ω. In the case of same characteristic impedance Z₀, when εᵣ is smaller, for example εᵣ=4, the structure area can be reduced. The diameter of the outer ring may therefore be smaller to achieve lower impedance. In other words, with the glass material the dimensions of the ring structure may be reduced. For example with a low-loss glass having εᵣ=4 and for a characteristic impedance of 50Ω, ring structure dimension may be b=a*exp (1.677). Based on the different matching of characteristic impedance (e.g. 50Ω or 70Ω), the coaxial-like structure may be flexibly realized through laser processing.

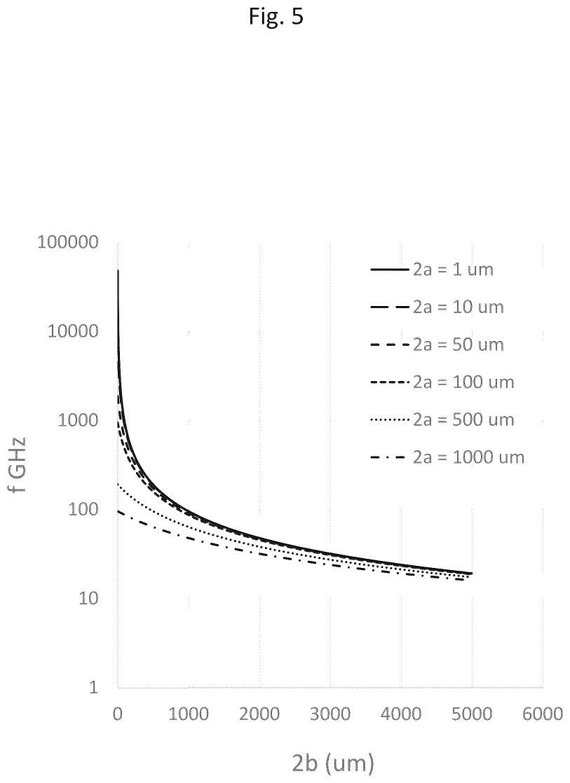

FIG. 5 shows a diagram of the cutoff frequency of a vertical interconnect micro-component based on a low-loss glass substrate, for example as mentioned above. The cutoff frequency may be approximated as f_{c}(GHz)=190.85/(\sqrt{εᵣ}(2a+2b)) for 2a and 2b in millimeters. For example with a specific cutoff frequency, values for a, b may result, based on which a value for Z₀ may result. For a low-loss glass substrate, for example as mentioned above, the following examples may be provided:
1) 2a=1000 um, 2b=5000 um, f_{cutoff}=15.9 GHz→Z₀=48.27Ω
2) 2a=1 um, 2b=5000 um, f_{cutoff}=19.1 GHz→Z₀=255.51Ω
3) 2a=1000 um, 2b=2000 um, f_{cutoff}=31.8 GHz→Z₀=20.7Ω

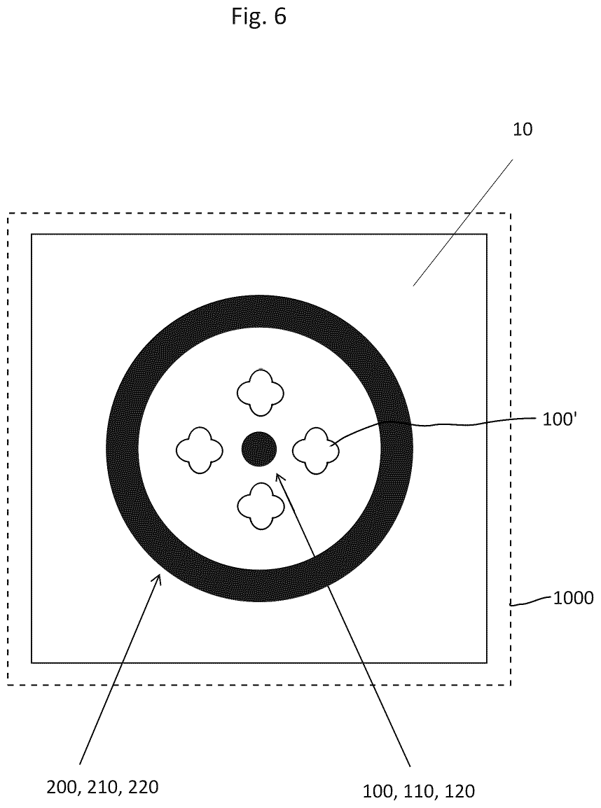

FIG. 6 shows an alternative embodiment in which the outer through connector structure 200 comprises a continuous annular outer cavity 210 in the glass substrate 10, which is fully filled with solid conductor material.

However, it is noted that the previous embodiments are generally preferred due to ease of manufacturing as well as mechanical stability of the substrate, while still retaining the desired impedance value needed to operate at high frequencies. While FIG. 6 shows only one inner through connector, it is noted above in the Summary of the Invention that it is also possible that the vertical interconnect micro-component instead comprises a plurality of inner through connectors 100′, shown here as dotted lines solely schematically. These connectors 100′ may be formed by adjoining hemispherical depressions meeting to form ridges as shown. The glass substrate 10 I spart of an integrated circuit 1000 also shown solely schematically by dotted lines.

Summarizing, in the present invention, an entire glass substrate is used. It is structured by laser processing, frequently (but not necessarily) followed by chemical etching and the substrate itself is the insulator. In addition, the use of a low dielectric glass may enable closer packing of metal coaxial through-holes for use at high frequencies.

It is noted that producing a vertical interconnect micro-component with a glass substrate is rather unusual for the person skilled in the art, because producing the required structures in a glass substrate may be more complex, in particular in comparison to structuring a silicon-based semiconductor material. For example, when laser processing the ring structure, the dimension of the ring may need to be carefully controlled to avoid irregularities. Moreover, differences in interface stress between the inner wall and the outer wall of the ring structure may need to be controlled to avoid defects such as cracks which would lead to structural failure. Furthermore, laser ablation may be a comparatively slow process. However, the inventive method may require less steps than structuring a silicone material and thus be advantageous. Moreover, glass may inherently have a large enough resistivity, so that no additional insulator layer is required. For example, low-loss glass may be used as the substrate. According to α=π\sqrt{εᵣ}tanδ/λ₀, if the dielectric constant εᵣ is small, the dielectric loss factor may be reduced.

What is claimed is:

1-15. (canceled)

16. A vertical interconnect micro-component adapted for radio frequency signal transmission, the vertical interconnect micro-component comprising:
a glass substrate with a first side and a second side opposite to the first side;
at least one inner through connector formed in the glass substrate, the inner through connector including an inner cavity in the glass substrate extending from the first side to the second side of the glass substrate, the inner cavity being fully or partially filled with solid conductor material; and
an outer through connector structure formed in the glass substrate and surrounding the at least one inner through connector, the outer through connector structure including at least one more outer cavity in the glass substrate extending from the first side to the second side of the glass substrate, each of the at least one outer cavity being fully or partially filled with solid conductor material.

17. The vertical interconnect micro-component as recited in claim 16 wherein the at least one outer cavity includes a plurality of spaced-apart annularly or symmetrically arranged outer cavities; or the at least one outer cavity includes a continuous annular outer cavity.

18. The vertical interconnect micro-component as recited in claim 16 wherein the inner through connector is arranged coaxially in a center of the outer through connector structure or the at least one inner through connector includes a plurality of inner through connectors.

19. The vertical interconnect micro-component as recited in claim 16 wherein the at least one inner through connector includes a plurality of inner through connectors arranged in central symmetry with respect to the outer through connector structure.

20. The vertical interconnect micro-component as recited in claim 16 wherein the vertical interconnect micro-component is adapted for the transmission of at least one frequency in the range of 1 MHz to 300 GHz, or wherein the vertical interconnect micro-component defines an upper cutoff frequency being the highest transmissible frequency, wherein the upper cutoff frequency is below 300 GHz.

21. The vertical interconnect micro-component as recited in claim 16 wherein the vertical interconnect micro-component is adapted for the transmission of at least one frequency in the range of 1 GHz to 200GHz, or wherein the vertical interconnect micro-component defines an upper cutoff frequency being the highest transmissible frequency, wherein the upper cutoff frequency is below 200 GHz.

22. The vertical interconnect micro-component as recited in claim 16 wherein the vertical interconnect micro-component defines a characteristic impedance in the range of 30 Ohm to 100 Ohm.

23. The vertical interconnect micro-component as recited in claim 16 wherein the vertical interconnect micro-component defines a characteristic impedance in the range of 50 Ohm to 100 Ohm.

24. The vertical interconnect micro-component as recited in claim 16 wherein the at least one inner through connector defines an outer diameter in the range of 1 μm to λ, or wherein the outer through connector structure defines an inner diameter in the range of 1 μm to λ,
wherein λ is an upper wavelength of a microwave band selected from the group consisting of: L band, S band, C band, X band, Kᵤ band, K band, Kₐ band, Q band, U band, V band, W band, F band, D band, or a band above the D band, a band with an upper frequency of 300 GHz.

25. The vertical interconnect micro-component as recited in claim 16 wherein the at least one inner through connector defines an outer diameter in the range of 1 μm to 1000 μm, or wherein the outer through connector structure defines an inner diameter in the range of 1 μm to 1100 μm.

26. The vertical interconnect micro-component as recited in claim 16 wherein the relative permittivity (εᵣ) of the glass substrate at 5 GHz is lower than 10 or wherein the thickness of the glass substrate is in the range of 0.03 mm to 3 mm.

27. The vertical interconnect micro-component as recited in claim 16 wherein the relative permittivity (εᵣ) of the glass substrate at 5 GHz is in the range of 1.0 to 5.0, or wherein the thickness of the glass substrate is in the range of range of 0.05 mm to 1 mm.

28. The vertical interconnect micro-component as recited in claim 16 wherein the solid conductor material embedded in the at least one inner cavity or in the at least one outer cavity is a metal.

29. The vertical interconnect micro-component as recited in claim 28 wherein the metal is selected from the group consisting of copper, aluminum, gold, palladium, and carbon.

30. The vertical interconnect micro-component as recited in claim 16 wherein the at least one inner cavity or the at least one outer cavity is characterized by a wall having a plurality of rounded, substantially hemispherical depressions adjoining one another.

31. A method for producing a vertical interconnect micro-component, the method comprising:
providing a glass substrate with a first side and a second side opposite to the first side;
producing at least one inner cavity and at least one outer cavity by directing a laser beam onto one of the sides of the glass substrate to form filament-shaped flaws in the volume of the glass substrate, and forming the at least one inner cavity and the at least one outer cavity at the filament-shaped flaws; and
embedding a solid conductor material in the at least one inner cavity and at least one outer cavity to form at least one inner through connector and at least one outer through connector structure in the glass substrate.

32. The method as recited in claim 31 wherein the embedding of the solid conductor material includes first depositing an adhesion layer on the at least one inner cavity and at least one cavity.

33. The method as recited in claim 31 wherein the embedding of a solid conductor material includes depositing a seed layer on the at least one inner cavity and at least one cavity.

34. The method as recited in claim 31 further comprising, after the embedding, removing excess material from the first or second side.

35. An integrated circuit comprising the vertical interconnect micro-component as recited in claim 16.
